(19) United States
(12) Patent Application Publication
(10) Pub. No.: US 2026/0098333 A1
(43) Pub. Date: Apr. 9, 2026

(54) INHIBITED OXIDE DEPOSITION FOR REFILLING SHALLOW TRENCH ISOLATION

(71) Applicant: Lam Research Corporation, Fremont, CA (US)

(72) Inventors: Jonathan Grant BAKER, King City, OR (US); Pulkit AGARWAL, Beaverton, OR (US); Douglas Walter AGNEW, Portland, OR (US); Jennifer Leigh PETRAGLIA, Portland, OR (US); Dae-Jin PARK, Lake Oswego, OR (US); Aaron FELLIS, Lake Oswego, OR (US)

(21) Appl. No.: 19/113,581

(22) PCT Filed: Sep. 8, 2023
(86) PCT No.: PCT/US2023/073760

§ 371 Date: Mar. 20, 2025

Related U.S. Application Data
(60) Provisional application No. 63/379,281, filed on Oct. 12, 2022.

(51) Int. Cl. C23C 16/04; C23C 16/40; C23C 16/455; C23C 16/505; H10P 14/60; H10P 14/692; H10W 10/00

(52) U.S. Cl. CPC C23C 16/045; C23C 16/401; C23C 16/45536; C23C 16/505; H10P 14/6506; H10P 14/69215; H10W 10/021

(57) ABSTRACT

Examples are disclosed relate to using an inhibitor with a silicon oxide ALD deposition process to refill recesses in STI regions. One example provides a method of processing a substrate. The method comprises depositing an inhibitor on the substrate, wherein a concentration of the inhibitor on a gate structure of the substrate is greater relative to the concentration of the inhibitor on a recessed shallow trench isolation (STI) region of the substrate. The method further comprises depositing a layer of silicon oxide on the substrate, the inhibitor inhibiting growth of the layer of silicon oxide such that the layer of silicon oxide is thicker on the recessed STI region and thinner on the gate structure.

### BACKGROUND

Semiconductor device fabrication processes may involve many steps of material deposition, patterning and removal to form integrated circuits on substrates. Various methods can be used to deposit films of materials onto a substrate. As an example, atomic layer deposition (ALD) forms a film using one or more deposition cycles. In an ALD deposition cycle, a film precursor is adsorbed onto a surface of a substrate disposed in a process chamber. Excess film precursor is purged from the chamber, and the adsorbed film precursor is chemically converted into a film on the substrate, for example, by oxidation. A highly conformal film of a target thickness can be grown via one or more deposition cycles.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

One example provides a method of processing a substrate. The method comprises depositing an inhibitor on the substrate, wherein a concentration of the inhibitor on a gate structure of the substrate is greater relative to a concentration of the inhibitor on a recessed shallow trench isolation (STI) region of the substrate. The method further comprises depositing a layer of silicon oxide on the substrate, the inhibitor inhibiting growth of the layer of silicon oxide such that the layer of silicon oxide is thicker on the recessed STI region and thinner on the gate structure.

In some such examples, the inhibitor alternatively or additionally comprises one or more of hydrogen, a fluorine-containing inhibitor, a carbon-containing inhibitor, or a nitrogen-containing inhibitor.

In some such examples, the inhibitor alternatively or additionally comprises one or more of hydrogen (H₂), fluorine (F₂), nitrogen (N₂), nitrogen trifluoride (NF₃), carbon tetrafluoride (CF₄), sulfur hexafluoride (SF₆), hydrogen fluoride (HF), xenon difluoride (XeF₂), ammonia (NH₃), an amine, a diamine, an aminoalcohol, an alkane, an alkene, an alkyne, a cyclic hydrocarbon, an alcohol, a diol, an aldehyde, an ester, an ether, a ketone, an alkyl halide, an alkyl amine, or an alkyl diamine.

In some such examples, the method alternatively or additionally comprises performing a passivation cycle to remove the inhibitor from the substrate.

In some such examples, performing the passivation cycle alternatively or additionally comprises performing the passivation cycle after completing a plurality of oxide deposition cycles.

In some such examples, the passivation cycle alternatively or additionally is performed after completing a first portion of oxide deposition cycles and before completing a second portion of oxide deposition cycles.

In some such examples, the inhibitor alternatively or additionally is deposited at a first pressure and silicon oxide is deposited at a second, different pressure.

In some such examples, the inhibitor and silicon oxide alternatively or additionally are deposited at a same pressure. In some such examples, depositing the inhibitor alternatively or additionally comprises depositing the inhibitor using plasma-enhanced atomic layer deposition (PEALD).

In some such examples, deposition of the inhibitor using PEALD alternatively or additionally comprises depositing the inhibitor using radio frequency energy with a first frequency component and a second frequency component, wherein the first frequency component has a higher frequency than the second frequency component.

In some such examples, the substrate comprises a terminal structure within the recessed STI region, and the method alternatively or additionally further comprises performing a post silicon oxide layer deposition etch to expose at least a portion of the terminal structure.

Another example provides a method of processing a substrate. The method comprises depositing an inhibitor on the substrate, wherein a concentration of the inhibitor on a hardmask and a gate structure of the substrate is greater relative to the concentration of the inhibitor on a recessed STI region of the substrate. The method further comprises depositing a layer of silicon oxide on the substrate, the inhibitor inhibiting growth of the layer of silicon oxide such that the layer of silicon oxide is thicker on the recessed STI region than on the hardmask and gate structure. The layer of silicon oxide overfills the recessed STI region to cover a terminal structure located within and extending above the recessed STI region of the substrate. The method further comprises performing a post silicon oxide layer deposition etch to expose at least a portion of the terminal structure.

In some such examples, the inhibitor alternatively or additionally comprises one or more of a fluorine-containing inhibitor, a carbon-containing inhibitor, or a nitrogen-containing inhibitor.

In some such examples, the inhibitor alternatively or additionally comprises one or more of H₂, F₂, N₂, NF₃, CF₄, SF₆, HF, XeF₂, NH₃, an aminoalcohol, a thiol, an alkane, an alkene, an alkyne, a cyclic hydrocarbon, an alcohol, a diol, an aldehyde, an ester, an ether, a ketone, an alkyl halide, an alkyl amine, or an alkyl diamine.

In some such examples, the method alternatively or additionally comprises performing a passivation cycle to remove the inhibitor from the substrate.

In some such examples, deposition of the inhibitor alternatively or additionally comprises using PEALD comprising a plasma using radio frequency energy with a first frequency component and a second frequency component, wherein the first frequency component has a higher frequency than the second frequency component.

Another example provides a method of processing a substrate. The method comprises depositing an inhibitor on the substrate, wherein a concentration of the inhibitor on a hardmask and a gate structure of the substrate is greater relative to the concentration of the inhibitor on a recessed shallow trench isolation (STI) region of the substrate. The method further comprises depositing a layer of silicon oxide on the substrate. The inhibitor inhibits growth of the layer of silicon oxide such that the layer of silicon oxide is thicker on the recessed STI region than on the hardmask and gate structure. The layer of silicon oxide fills the recessed STI region to a level partway up a terminal structure located within and extending above the recessed STI region of the substrate and also coats an upper portion of the terminal structure. The method further comprises performing a post silicon oxide layer deposition etch to expose at least a portion of the terminal structure.

In some such examples, the inhibitor alternatively or additionally comprises one or more of a fluorine-containing inhibitor, a carbon-containing inhibitor, or a nitrogen-containing inhibitor.

In some such examples, the inhibitor alternatively or additionally comprises one or more of H₂, F₂, N₂, NF₃, CF₄, SF₆, HF, XeF₂, NH₃, an amine, a diamine, an aminoalcohol, an alkane, an alkene, an alkyne, a cyclic hydrocarbon, an alcohol, a diol, an aldehyde, an ester, an ether, a ketone, an alkyl halide, an alkyl amine, or an alkyl diamine.

In some such examples, the method alternatively or additionally comprises performing a passivation cycle to remove the inhibitor from the substrate.

In some such examples, deposition of the inhibitor alternatively or additionally comprises using PEALD comprising a plasma using radio frequency energy with a first frequency component and a second frequency component, wherein the first frequency component has a higher frequency than the second frequency component.

### BRIEF DESCRIPTION OF THE DRAWINGS

FIGS. 1A-1C schematically show example structures formed in an example shallow trench isolation (STI) refilling process using a conformal deposition technique.

FIG. 2 shows a flow diagram illustrating an example process for refilling an STI region using an inhibited silicon oxide deposition.

FIG. 3 shows a flow diagram illustrating another example process for refilling a recessed STI region using an inhibited silicon oxide deposition.

FIGS. 4A-4H schematically show example structures formed in an example implementation of the process of FIG. 3.

FIG. 5 shows a flow diagram illustrating another example process for refilling a recessed STI region using an inhibited oxide deposition.

FIGS. 6A-6H schematically show example structures formed in an example implementation of the process of FIG. 5.

FIG. 7 shows a flow diagram illustrating an example method for performing ALD processing using a plurality of ALD cycles and an equal number of inhibition and passivation cycles.

FIG. 8 shows a flow diagram illustrating an example method for performing ALD processing using a plurality of ALD cycles and unequal number of inhibition and passivation cycles.

FIG. 9 shows a flow diagram illustrating an example method for performing ALD processing using a plurality of ALD cycles and inhibition cycles with no passivation.

FIG. 10 shows a flow diagram illustrating an example method for performing ALD processing using a plurality of ALD cycles and inhibition cycles and a final passivation cycle.

FIG. 11 shows a flow diagram illustrating an example sequence for performing ALD processing using a plurality of ALD cycles, inhibition cycles and passivation cycles performed at one or more of a same pressure or a same gas flow rate.

FIG. 12 shows a flow diagram illustrating an example sequence for performing ALD processing using a plurality of ALD cycles and inhibition cycles performed at one or more of a same pressure or a same gas flow rate, and with no passivation.

FIG. 13 shows a flow diagram illustrating an example sequence for performing ALD processing using a plurality of ALD cycles with no passivation, and using a combined oxidation and inhibition cycle.

FIG. 14 shows a block diagram of an example processing tool.

FIG. 15 shows a block diagram of an example computing device.

### DETAILED DESCRIPTION

The term “alcohol” may generally represent hydrocarbon compounds comprising a general formula of R—OH, where R is an aromatic or aliphatic group. Alcohols may have more than one OH group (polyols). For example, diols have two OH functional groups. Example alcohols comprise methanol, ethanol, and propanol.

The term “aldehyde” may generally represent hydrocarbon compounds comprising a terminal carbonyl group. Aldehydes comprise a general formula of R—CHO where R is an aromatic or aliphatic group. Example aldehydes comprise formaldehyde and acetaldehyde.

The term “aliphatic” may generally represent organic compounds lacking aromatic groups.

The term “alkane” may generally represent compounds comprising a general formula CₙH₂ₙ₊₂ and substituted variants thereof. Example alkanes include methane, ethane, propane, and butane.

The term “alkene” may generally represent hydrocarbon compounds comprising at least one carbon-carbon double bond. Alkanes comprising one carbon-carbon double bond may be represented by a general formula of CₙH₂ₙ and substituted variants thereof. Example alkenes include ethylene, propylene, and butylenes. Alkenes may have more than one carbon-carbon double bond, such as dienes, allenes, and cumulenes.

The term “alkyl amine” may generally represent hydrocarbon compounds comprising a nitrogen with 1 to 3 alkyl substituents and 0 to 2 H substituents. Alkyl amines comprise primary, secondary, tertiary, and cyclic amines. Examples of alkyl amines include methylamine, dimethylamine, trimethylamine, and piperidine.

The term “alkyl halide” may generally represent hydrocarbon compounds comprising a halogen. Examples of alkyl halides comprise ethyl fluoride (fluoroethane), isopropyl bromide (2-bromopropane), and t-butyl chloride (2-chloro-2-methylpropane). Alkyl halides may comprise two or more halogen groups, such as 1,2-dichlorobutane.

The term “alkyne” may generally represent hydrocarbon compounds comprising at least one carbon-carbon triple bond. Alkynes comprising one carbon-carbon triple may be represented by a general formula of CₙH₂ₙ₋₂ and substituted variants thereof. Alkynes may have more than one carbon-carbon triple bond, such as diynes, which have two carbon-carbon triple bonds.

The term “aromatic” may generally represent a planar cyclic compound comprising pi bonding in resonance. The term “aromatic” comprises homocyclic compounds in which all atoms in a ring structure are carbon, and also heterocyclics in which one or more atoms in a ring structure are elements other than carbon (e.g. nitrogen).

The term “atomic layer deposition” (ALD) may generally represent a process in which a film (e.g., an oxide film) is formed on a substrate in one or more individual layers by sequentially adsorbing a precursor to a substrate and then chemically transforming the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth” and “deposition”, and variants thereof, also may be used to refer to film formation.

The terms “atomic layer deposition cycle” and “ALD cycle” may generally represent a single cycle of adsorbing a chemical precursor on a substrate surface and then chemically transforming the adsorbed chemical precursor to form a film layer on the substrate.

The term “ALD cycle comprising an inhibitor” may generally represent an ALD cycle that includes introduction of an inhibitor to a processing chamber during the cycle.

The term “cyclic hydrocarbon” may generally represent saturated and unsaturated hydrocarbon molecules comprising a closed ring structure, and substituted variants thereof. Example cyclic hydrocarbons include cyclopropane and cyclobutane. Example cyclic hydrocarbons also include aromatics such as benzene, toluene, and xylene.

The terms “etch”, “etching” and variants thereof may generally represent a process of removing material from a substrate surface. An etching process may encompass chemical and/or physical material removal mechanisms. A “dry etching” or a “dry etch” process is an etching process that utilizes gas phase etchants. A “wet etching” or a “wet etch” process is an etching process that utilizes liquid-phase etchants.

The term “ether” may generally represent hydrocarbon compounds comprising the general formula R—O—R′ where R and R′ are independently an aromatic or aliphatic group. Example ethers comprise diethyl ether, methyl phenyl ether, and cyclic ethers such as furan.

The term “ester” may generally represent hydrocarbon compounds comprising the general formula R—C(O)OR′ where R and R′ are independently any aromatic or aliphatic group and wherein R may alternatively comprise H. Examples esters comprise ethyl formate, methyl acetate, and ethyl acetate.

The term “gate structure” may generally represent a non-planar transistor gate in a metal oxide semiconductor (MOS) device. An example of a gate structure is a gate formed on a fin in a FinFET.

The term “hardmask” may generally represent a film that is more resistant to etching than polymer photoresists. Examples of hardmask materials may include silicon nitride, silicon oxynitride, silicon carbonitride and silicon oxycarbide films.

The term “inhibition cycle” may generally represent a process comprising introducing an inhibitor onto a substrate.

The term “inhibitor” may generally represent a compound that can be introduced into a processing chamber, that can be deposited nonconformally on a substrate surface, and that inhibits ALD growth of an oxide film. Suitable inhibitors include nitrogen-containing inhibitors, fluorine-containing inhibitors, and carbon-containing inhibitors.

Examples of suitable nitrogen-containing inhibitors may include nitrogen (N₂), ammonia (NH₃), amines, diamines, and aminoalcohols. In some examples, a nitrogen-containing inhibitor may comprise a mixture of H₂ and another gas. One example of such a mixture comprises an H₂/N₂ mixture.

Examples of suitable fluorine-containing inhibitors may include F₂, NF₃, SF₆, HF, XeF₂ and fluorocarbons such as CF₄ or C₂F₆.

Examples of suitable carbon-containing inhibitors may include alkanes, alkenes, alkynes, cyclic hydrocarbons, aromatics, alcohols, aldehydes, esters, ethers, ketones, aldehydes, alkyl halides, alkyl amines, and alkyl diamines. In some examples, the carbon-containing inhibitor may comprise an alkane comprising a general formula CₙH₂ₙ₊₂ in which n=1 to 10. Examples of suitable alkanes may include methane, ethane, propane, butane, pentane, hexane, and substituted variants thereof. Other examples of carbon-containing inhibitors may comprise an alkene, an alkyne, a cyclic hydrocarbon, an aromatic, an alcohol, a diol, an aldehyde, an ester, an ether, a ketone, an alkyl halide, an alkyl amine, or an alkyl diamine, including substituted variants thereof. In still other examples, the carbon-containing inhibitor may comprise a mixture of carbon-containing inhibitors. Examples of suitable alkenes (CₙH₂ₙ in which n=2 to 10, for an alkene with a single carbon-carbon double bond) may include ethene, propene, butene, and substituted variants thereof. Examples of suitable alkynes (CₙH₂ₙ₋₂ in which n=2 to 10, for an alkyne with a single carbon-carbon triple bond) may include acetylene, propyne, butyne, and substituted variants thereof. Examples of suitable cyclic hydrocarbons may include cyclobutene, cyclopentane, cyclohexane and substituted variants thereof. Examples of suitable aromatics may include benzene, toluene, pyridine, pyrimidine, and substituted variants thereof. Examples of suitable alcohols may include methanol, ethanol, propanol, and substituted variants thereof. Examples of suitable diols may include ethylene glycol, propylene glycol, hydroquinone, and substituted variants thereof. Examples of suitable aldehydes may include formaldehyde, acetaldehyde, and substituted variants thereof. Examples of suitable esters may include ethyl formate, methyl acetate, and ethyl acetate, and substituted variants thereof. Examples of suitable ethers may include diethyl ether, methyl phenyl ether, aromatic ethers such as furan, and substituted variants thereof. Examples of suitable ketones may include acetone, methyl ethyl ketone, and substituted variants thereof. Examples of suitable alkyl halides may include ethyl fluoride, isopropyl bromide, t-butyl chloride, and substituted variants thereof. Examples of suitable alkyl amines may include methylamine, dimethylamine, trimethylamine, piperidine, and substituted variants thereof. Examples of suitable alkyl diamines may include ethylenediamine, 1,3-diaminopropane, and substituted variants thereof.

The term “ketone” may generally represent hydrocarbon compounds comprising a non-terminal carbonyl. Ketones have the general formula R—C(O)—R′ where R and R′ are independently an aromatic or aliphatic group. Example ketones comprise acetone and methyl ethyl ketone.

The term “oxidant” may generally represent a gas species containing oxygen available for reacting with a film precursor to form an oxide film. Examples of oxidants comprise molecular oxygen (O₂), water vapor (H₂O), hydrogen peroxide (H₂O₂), and ozone (O₃).

The term “oxide deposition cycle” may generally represent a sequence of processes used to form an oxide layer. An example oxide layer is a silicon oxide layer.

The term “oxide film” comprise films of doped or undoped oxide. An example oxide film is silicon oxide (SiO₂).

The term “passivation” may generally represent a process cycle used to remove residual inhibitor from a substrate surface.

The term “passivation cycle” may generally represent a single passivation step.

The term “post silicon oxide layer deposition wet etch” may generally represent a wet etch performed after the completion of the silicon oxide layer deposition is completed. The wet etch is isotropic and may be performed using any suitable etchant. An example etchant may comprise dilute HF.

The term “processing chamber” may generally represent an enclosure in which chemical and/or physical processes are performed on substrates. The pressure, temperature and atmospheric composition within a processing chamber may be controllable to perform the chemical and/or physical processes.

The term “processing tool” may generally represent a machine including a processing chamber and other hardware configured to enable processing to be carried out in the processing chamber.

The terms “purge” and variants thereof may generally represent processes in which unwanted species are removed from a processing chamber.

The term “recessed STI region” may generally represent a portion of an STI region comprising a recess formed in an etching process, such as a gate etching process. The recess may have a relatively narrower opening and a relatively wider region deeper within the recess.

The term “remote plasma” may generally represent a plasma used to produce chemical species at a location remote from a surface being processed with the chemical species. A remote plasma may be used to produce chemical species for processing a substrate that is located outside of the plasma. A remote plasma also may be used to produce chemical species for cleaning processing chamber surfaces that are located outside of the plasma.

The term “remote plasma enhanced atomic layer deposition” (remote PEALD) may generally represent an ALD process that utilizes a remote plasma to generate reactive gas species.

The terms “shallow trench isolation”, “STI”, “STI region”, and variants thereof may generally represent a structure that separates and isolates neighboring transistors or memory cells. An STI comprises a trench that is etched and filled with an insulating material.

The term “silicon-containing precursor” may generally represent any material that can be introduced into a processing chamber in a gas phase to form a silicon-containing film on the substrate. Example silicon-containing precursors for forming silicon-containing films using PEALD may comprise materials having the general structure:

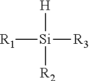

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups.

More specific example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following: Hₓ—Si—(OR)_{y}, where x=1-3, x+y=4 and each R is a substituted or unsubstituted alkyl, alkenyl, alkynyl or aromatic group; and Hₓ(RO)_{y}, —Si—Si—(OR)_{y}Hₓ, is a substituted or unsubstituted alkyl, alkenyl, alkynyl or aromatic group.

Further examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

Further, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino)silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group.

In some examples, a halogen-containing silane may be used such that the silane includes at least one hydrogen atom. Such a silane may have a chemical formula of SiXₐH_{y} where y≥1. For example, dichlorosilane (H₂SiCl₂) may be used in some examples.

The term “silicon oxide deposition cycle” may generally represent an ALD cycle that deposits a layer of silicon oxide deposition.

The term “substrate” may generally represent any object on which a film can be deposited.

The term “substrate support” may generally represent any structure for supporting a substrate in a processing chamber. Examples comprise chucks, pedestals, and showerhead pedestals used for backside deposition processes.

The term “terminal structure” may generally represent one or more of a source structure or a drain structure of a transistor.

Semiconductor devices may employ the use of non-planar gate structures. Non-planar gate structures include fin field effect transistors (FinFETs). A FinFET comprises a gate structure located on two or more sides of a channel. The gate structure is formed on part of a raised fin-like structure. The gate structure is adjacent to STI regions. Terminal structures (source and drain structures) are located within the STI regions.

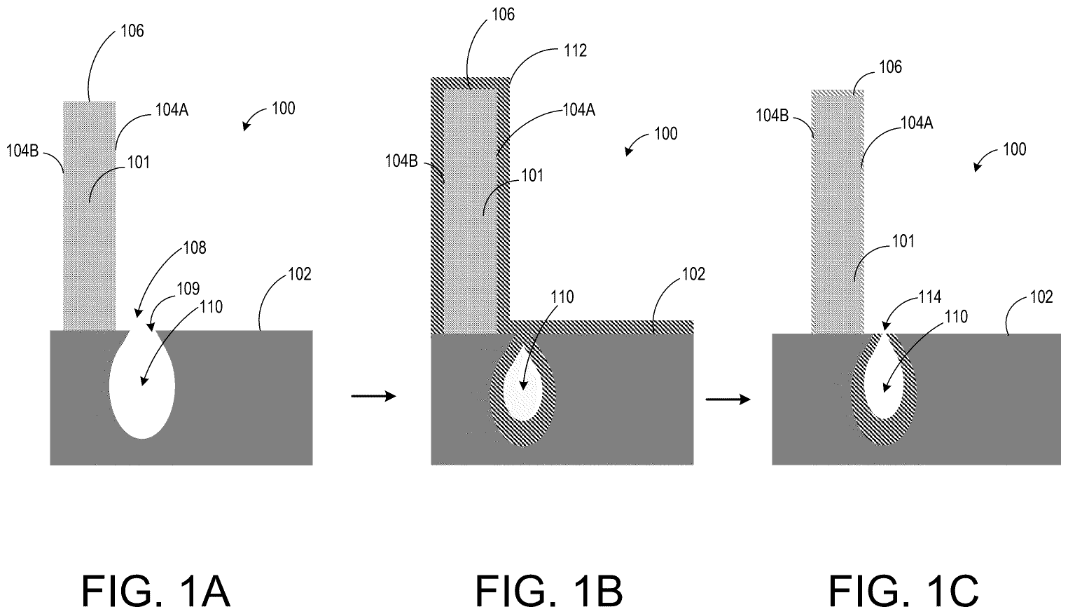

The fabrication of non-planar gate structures involves an etching step that may etch a recess into STI regions adjacent to the non-planar gate structures. This forms recessed STI regions. In some semiconductor device manufacturing processes, it may be desirable to refill the recessed STI regions with oxide. FIGS. 1A-IC schematically show example structures formed in an example shallow trench isolation (STI) refilling process using a conformal deposition technique. For example, FIG. 1A schematically shows a substrate 100 comprising a gate structure 101 with a top surface 106 and sides 104A, 104B. The gate structure 101 is adjacent to recessed STI region 102. The recessed STI region 102 is formed on an underlying substrate. The recessed STI region 102 has been etched. As such, the recessed STI region 102 comprises a recess 108. The recess 108 comprises a entrant region 109 that is narrower than the interior region 110.

A dielectric material may be used to fill the recess 108 in the recessed STI region 110. Any suitable dielectric material may be used. In some examples, the dielectric material may be the same as the STI material. As a more specific example, the dielectric material may comprise silicon oxide. Referring to FIG. 1B, a dielectric material is deposited by ALD to form a conformal film 112 to fill the recess 108. However, the depicted conformal film 112 fills the entrant region 109 before filling the interior region 10 which results in plugging the opening of the recess 108. The interior region 110 may remain unfilled with silicon oxide, as shown in FIG. 1B.

Further, the conformal deposition also deposits the film 112 on surfaces 104A, 104B and 106 of the gate structure 101. Thus, an etching process may be used to remove the film 112 from gate structure surfaces 104A, 104B and 106. Prolonged etching may potentially damage the surfaces 104A, 104B and 106, referring to FIG. 1C of the gate structure 101. Such damage may degrade the device performance. Prolonged etching may also form an opening 114. The opening 114 may impact device reliability.

Accordingly, examples are disclosed that relate to refilling a recessed STI region adjacent to a nonplanar gate structure. Briefly, the disclosed examples deposit an inhibitor on the substrate, wherein a concentration of the inhibitor on a gate structure of the substrate is greater relative to the concentration of the inhibitor on a recessed STI region of the substrate. The disclosed examples additionally deposit a layer of silicon oxide on the substrate. The inhibitor inhibits growth of the layer of silicon oxide such that the layer of silicon oxide is thicker on the recessed STI region than on the gate structure. The thinner silicon oxide on the gate structure may be removed by a relatively short duration etch, such as a wet etch. A relatively short duration etch reduces the probability of damaging the gate structure surface compared to a relatively longer duration etch.

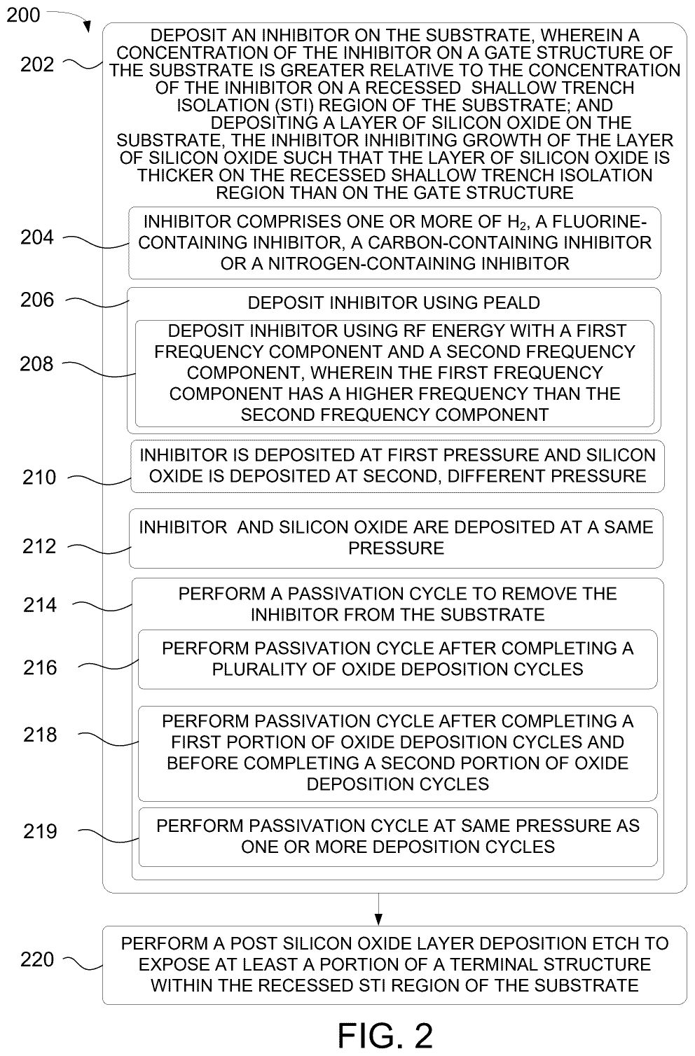

FIG. 2 shows a flow diagram depicting an example method 200 for processing a substrate. The method 200 comprises, at step 202, depositing an inhibitor on the substrate, wherein a concentration of the inhibitor on a gate structure of the substrate is greater relative to the concentration of the inhibitor on a recessed STI region of the substrate. Within the recessed STI region, a concentration of inhibitor is higher at an entrant region of the recessed STI region and lower deeper within the recessed STI region. Continuing with step 202, the method 200 also comprises depositing a layer of silicon oxide on the substrate. The inhibitor inhibits growth of the layer of silicon oxide such that the layer of silicon oxide is thicker on the recessed STI region than on the gate the structure. This may facilitate removal of the silicon oxide from the gate region by a subsequent etching process. Further, by depositing a higher concentration of inhibitor on the entrant region compared to the recessed STI region, the recessed STI region may be filled without forming a void.

Any suitable inhibitor may be used. In some examples the inhibitor may comprise one or more of a fluorine-containing inhibitor, a carbon-containing inhibitor, or a nitrogen-containing inhibitor, as indicated at step 204. Inhibitors may physisorb and/or chemisorb on substrate surfaces in various examples. For example, fluorine-containing inhibitors may chemisorb on substrate surfaces. More particularly, a plasma deposition process may be used to deposit a fluorine-containing inhibitor. The plasma creates reactive fluorine species from the fluorine-containing inhibitor. The reactive fluorine species react with hydroxyl (OH) groups on a silicon oxide surface to replace the H and form a fluorine-terminated surface. Example fluorine-containing inhibitors may include one or more of F₂, NF₃, CF₄, SF₆, HF or XeF₂. Nitrogen-containing inhibitors may also chemisorb on substrate surfaces. For example, nitrogen-containing inhibitors may be deposited by plasma to form reactive nitrogen species that react with —OH groups on a silicon oxide surface to bond to the silicon oxide surface. Example nitrogen-containing inhibitors may include one or more of N₂, NH₃, amines, diamines or aminoalcohols. In some examples, an inhibitor may comprise a mixture of hydrogen (H₂) and another species such as N₂. Fluorine-containing and nitrogen-containing inhibitors may act by inhibiting silicon oxide film nucleation on an inhibited surface.

Carbon-containing inhibitors may primarily physisorb on substrate surfaces. Carbon-containing inhibitors compete with silicon-containing precursors or other silicon oxide film precursors for oxygen. Thus, carbon-containing precursors reduce the amount of oxygen that is available for oxidation of silicon oxide film precursors. This slows the rate of silicon oxide film growth. Example carbon-containing inhibitors may include one or more of an alkane, an alkene, an alkyne, a cyclic hydrocarbon, an alcohol, a diol, an aldehyde, an ester, an ether, a ketone, an alkyl halide, an alkyl amine, or an alkyl diamine, including substituted variants of such molecules. In some examples, the carbon-containing inhibitor may comprise an alkane comprising a general formula CₙH₂ₙ₊₂ in which n=1 to 10. Examples of suitable alkanes may include methane, ethane, propane, butane, pentane, hexane, and substituted alkanes. Other examples of carbon-containing inhibitors may comprise an alkene, an alkyne, a cyclic hydrocarbon, an aromatic, an alcohol, a diol, an aldehyde, an ester, an ether, a ketone, an alkyl halide, an alkyl amine, or an alkyl diamine. In still other examples, the carbon-containing inhibitor may comprise a mixture of carbon-containing inhibitors. Examples of suitable alkenes (CₙH₂ₙ in which n=2 to 10, for an alkene with a single carbon-carbon double bond) may include ethene, propene, and butene. Examples of suitable alkynes (CₙH₂ₙ₋₂ in which n=2 to 10, for an alkyne with a single carbon-carbon triple bond) may include acetylene, propyne, and butyne. Examples of suitable cyclic hydrocarbons may include cyclobutane, cyclopentane and cyclohexane. Examples of suitable aromatics may include benzene, toluene, pyridine, and pyrimidine. Examples of suitable alcohols may include methanol, ethanol, and propanol. Examples of suitable diols may include ethylene glycol, propylene glycol, and hydroquinone. Examples of suitable aldehydes may include formaldehyde and acetaldehyde. Examples of suitable esters may include ethyl formate, methyl acetate, and ethyl acetate. Examples of suitable ethers may include diethyl ether, methyl phenyl ether, and aromatic ethers such as furan. Examples of suitable ketones may include acetone and methyl ethyl ketone. Examples of suitable alkyl halides may include ethyl fluoride, isopropyl bromide, and t-butyl chloride. Examples of suitable alkyl amines may include methylamine, dimethylamine, trimethylamine, and piperidine. Examples of suitable alkyl diamines may include ethylenediamine and 1,3-diaminopropane. Suitable carbon-containing inhibitors also may include substituted variants of such molecules.

The inhibitor may be deposed in any suitable manner. In some examples, the inhibitor may be deposited using PEALD, as indicated at step 206. PEALD may provide sufficient activation to form reactive inhibitor species from inhibitor molecules. In some examples, the PEALD process for inhibitor deposition may use RF energy with a higher frequency component and a lower frequency component as indicated at step 208. The higher frequency component may provide the activation energy to form the desired reactive inhibitor species to adsorb to the substrate. The lower frequency (LF) component may be used to direct the reactive inhibitor species to the substrate. The term “inhibitor” is used herein to represent the inhibitor molecule(s) introduced into the chamber, reactive inhibitor species formed in a plasma, and the inhibitor species adsorbed to a substrate surface.

In some examples, the higher frequency RF energy component may comprise a power in a range of 50-1500 W. Increasing the power of the higher frequency component may lead to stronger inhibition. The lower frequency component may be used to direct the inhibitor to the substrate. The lower frequency RF power may comprise a power in a range of 0-1500 W. Increasing the power of the lower frequency component may drive inhibitor farther down along a gate structure and/or farther into a recess. Increasing the inhibition time, the inhibitor partial pressure and the inhibitor flow rate may also lead to stronger inhibition. In some examples, the inhibition time may be varied in the range of 0.1-30 s. In other examples, any other suitable inhibition time may be used. In examples where NF₃ is used as an inhibitor, the inhibitor flow rate may be varied from 5-250 sccm. In other examples, any other suitable flow rate of inhibitor may be used. Further, in some examples, the inhibitor may be deposited at a pressure ranging from 0.1-30 torr. In other examples, the inhibitor may be deposited at any other suitable pressure outside of this range.

In some examples, the inhibitor may be deposited at a pressure that is different from the silicon oxide deposition pressure, as indicated at step 210. In other examples, the inhibitor and silicon oxide may be deposited at a same pressure, as indicated at step 212. In examples where the inhibitor and silicon oxide are deposited at the same pressure, the processing time on the processing tool may be reduced. This may result in a higher throughput.

In some examples, the inhibitor may be removed by a passivation cycle, as indicated at step 214. Passivation cycles, silicon oxide deposition cycles and inhibition cycles may be performed in different permutations and combinations. Examples of different orders and combinations of these cycles are discussed below. In other examples, an inhibitor may be removed without a passivation cycle. For example, a carbon-containing inhibitor may be removed by oxidation during film precursor oxidation.

In some examples, a passivation cycle may be performed after completing a plurality of silicon oxide deposition cycles, as indicated at step 216. As one such example, a passivation cycle may be performed to remove the inhibitor from gate and other surfaces after completion of silicon oxide deposition. In other examples, a passivation cycle may be performed after a first portion of the silicon oxide deposition but before completing a second portion of the silicon oxide deposition cycle, as indicated at step 218. Such an example may include removing the inhibitor from an entrance of a recess in a recessed STI region. This may be performed to allows subsequent silicon oxide deposition to seal the recess. Where a fluorine-containing inhibitor or a nitrogen-containing inhibitor is used, a passivation cycle may comprise exposing the inhibitor adsorbed to the substrate surface to one or more of H₂ or O₂. Thermal and/or plasma energy may be used to facilitate the passivation. In some examples, the passivation cycle may be performed at a pressure that is different from deposition pressures. In other examples, passivation may be performed at a same pressure as one or more deposition cycles, at step 219. Performing passivation at a same pressure as one or more deposition cycles may help to improve throughput. This is because a time between deposition and passivation may be reduced.

Following the deposition of the silicon oxide on the substrate, an etch is performed, as indicated at step 220. The etch removes silicon oxide such that at least a portion of a terminal structure is exposed. Any suitable etch process may be used. Examples include wet etch processes and dry etch processes. In some examples, a wet etch chemistry may include dilute HF.

The silicon oxide layer for refilling the recessed STI region may be deposited in any suitable thickness. In some examples, the silicon oxide layer is overfilled to cover a terminal structure. Then, the silicon oxide layer is etched back to reveal at least a portion of the terminal structure.

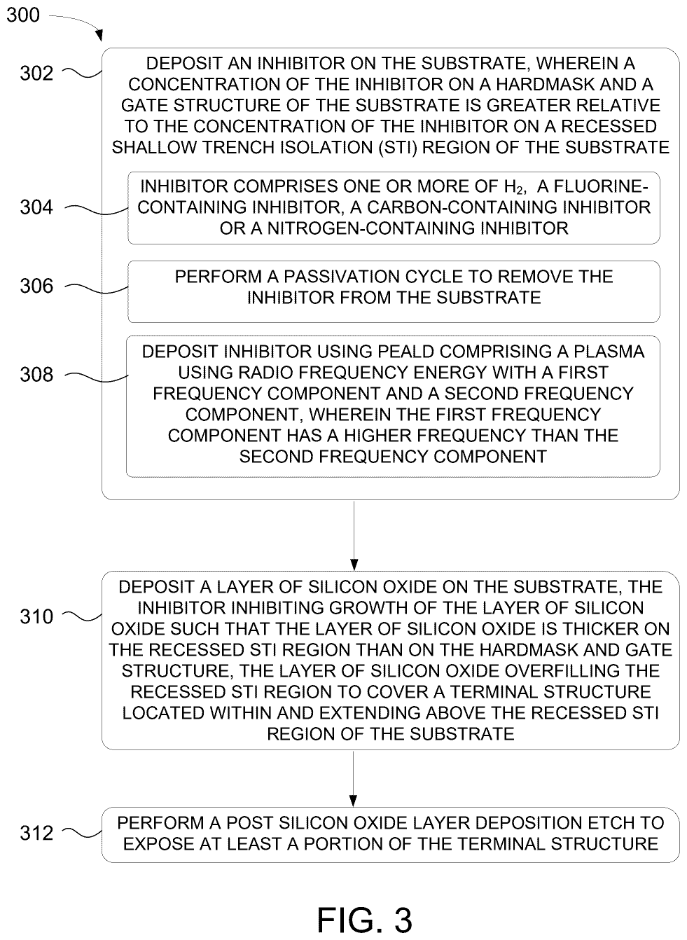

FIG. 3 illustrates an example method 300 for processing a substrate. The substrate comprises a hardmask disposed on a gate structure. The substrate also comprises a recessed STI region adjacent to the gate structure and a terminal structure located within the recessed STI region. The terminal structure extends above the recessed STI region. The terminal structure may comprise a source structure and/or a drain structure.

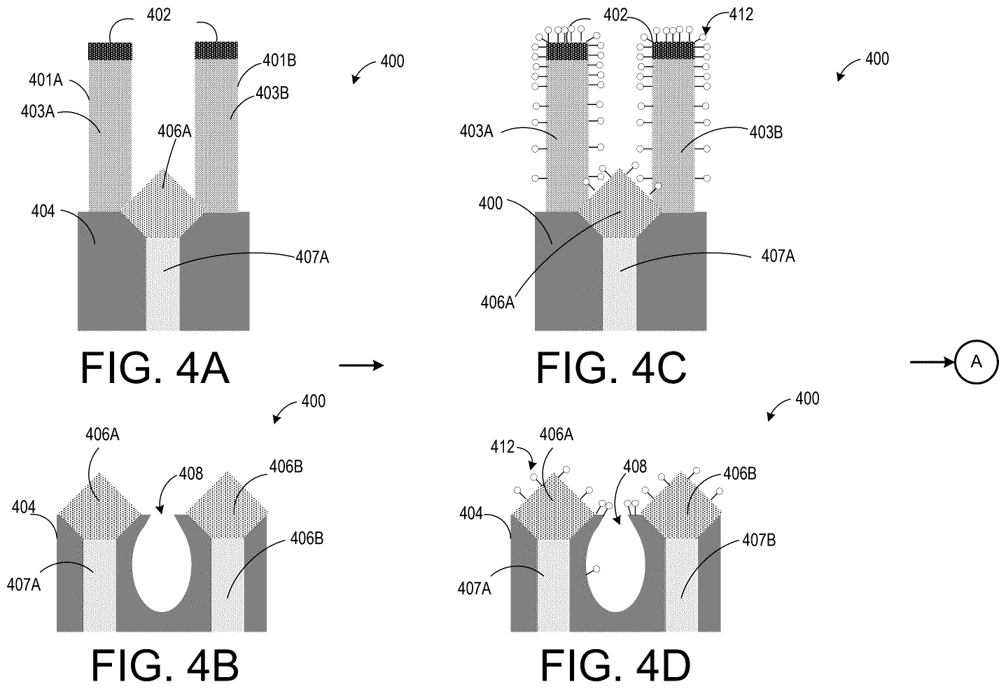

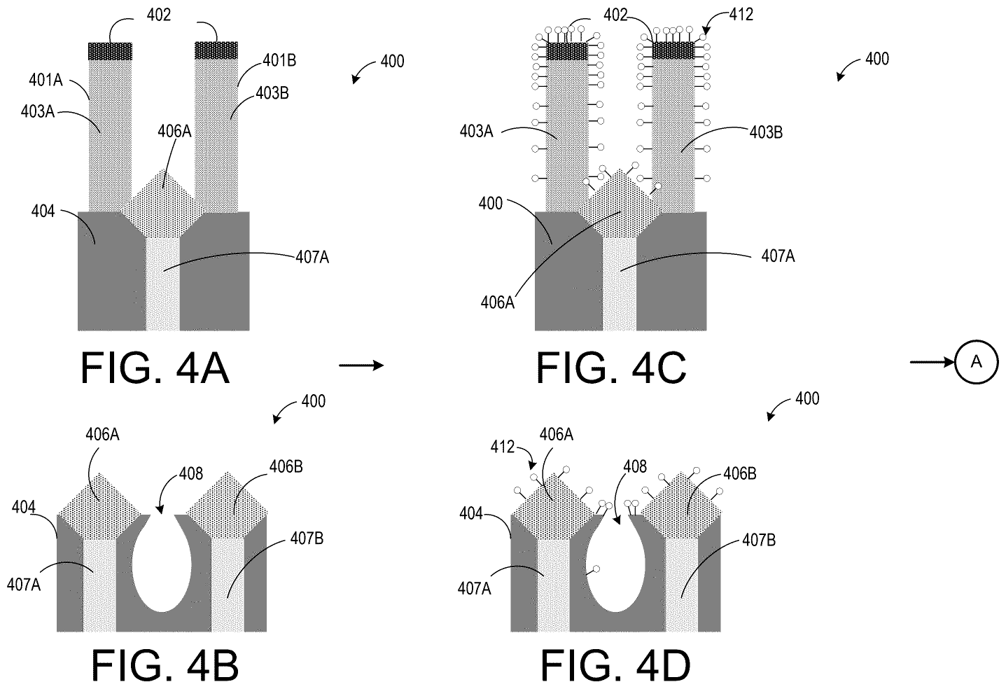

FIGS. 4A and 4B illustrate orthogonal views of a substrate 400 comprising a hardmask 402 disposed on gate structures 403A, 403B. The FIGS. 4A and 4B further illustrate a recessed STI region 404, and terminal structures 406A, 406B disposed on doped polysilicon structures 407A, 407B, respectively. The recessed STI region 404 comprises a recess 408.

Referring back to FIG. 3, the method 300 comprises, at step 302, depositing an inhibitor on the substrate under conditions that deposit a higher concentration of the inhibitor on the hardmask and gate structure and a lower concentration on the recessed STI region. FIGS. 4C and 4D, which are orthogonal views of the substrate 400, schematically show an inhibitor 412. The inhibitor 412 deposits at a higher concentration on the top surfaces of the gate structures 403A, 403B compared to the lower regions. FIG. 4D shows that the inhibitor 412 deposits at a higher concentration on the entrant region of the recess 408 compared to deeper regions of recess 408. Further, the terminal structures 406A, 406B comprise a higher concentration of the inhibitor 412 compared to the recessed STI region 404 and the recess 408.

Any suitable inhibitor may be used. In some examples, the inhibitor may comprise one or more of a fluorine-containing inhibitor, a carbon-containing inhibitor, or a nitrogen-containing inhibitor, as indicated at step 304 in FIG. 3. The inhibitor may be deposited on the substrate under processing conditions such that the concentration of the inhibitor is higher on surfaces where no silicon oxide deposition is desired.

In some examples, the inhibitor may be removed by a passivation cycle, as indicated in FIG. 3 at step 306. Passivation cycles, silicon oxide deposition and inhibitor deposition cycles may be performed in different permutations and combinations, as discussed below. In other examples, an inhibitor may be removed without a passivation cycle. For example, a carbon-containing inhibitor may be removed by oxidation during film precursor oxidation.

The inhibitor deposition conditions may depend on the nature of the substrate, the nature of the inhibitor and silicon oxide deposition conditions. In some examples, the inhibitor may be deposited using PEALD that comprises a plasma with a higher frequency RF energy and a lower frequency RF energy component, as indicated at step 308. In some examples, the higher frequency RF energy component may comprise a power in a range of 50-1500 W. Increasing the energy of the higher frequency component may lead to stronger inhibition. The lower frequency component may be used to direct the inhibitor to the substrate. In some examples, the lower frequency RF energy component may comprise a power in a range of 0-1500 W. Increasing the energy of the lower frequency component may lead to stronger inhibition.

Increasing the inhibition time, the inhibitor partial pressure and the inhibitor flow rate may also lead to stronger inhibition. In some examples, the inhibitor exposure time may comprise a value in a range of 0.1-30 s. Further, in some examples, the inhibitor may comprise a flow rate having a value within a range of 5-250 sccm. In other examples, any of these parameters may have a value outside of the stated example range for the parameter.

The method 300 further comprises, at step 310, depositing a layer of silicon oxide on the substrate. The inhibitor inhibits growth of the layer of silicon oxide such that the layer of silicon oxide is thicker on the recessed STI region and thinner on the hardmask and gate structure. Further, the layer of silicon oxide overfills the recessed STI region to cover the terminal structure. The overfill helps to ensure that the recessed STI regions are filled with silicon oxide, accounting for variations in recessed STI regions across the substrate. The layer of silicon oxide also covers the terminal structure on the substrate.

Orthogonal views FIGS. 4E and 4F show an example of an overfill of silicon oxide 410. The overfill of silicon oxide 410 is such that the top surfaces of the terminal structures 406A and 406B are covered by overfill of silicon oxide 410 in FIGS. 4E and 4F. A thinner layer of the silicon oxide 410 deposits on the surfaces of the gate structures 403A and 403B and the hardmask 402 due to the inhibitor.

Continuing with FIG. 3, the method 300 further comprises, at step 312, performing a post silicon oxide layer deposition wet etch to expose at least a portion of the terminal structure. This is shown schematically in orthogonal views FIGS. 4G and 4H. Any suitable wet etch process may be used. In some examples, a wet etch process may use dilute HF. The wet etch process may be performed for a sufficient time such that surfaces of the terminal structures 406A, 406B are exposed. Similarly, silicon oxide may be removed from hardmask 402 and surfaces of the gate structures 403A, 403B. A longer and/or more aggressive wet etch process may be used for a larger overfill. The hardmask disposed on the gate structure surface may prevent damage to the gate structure during the wet etch process. While FIGS. 4G and 4H show all oxide removed from the gate structure and terminal structures, in some examples a thin oxide layer may remain. Such a layer may be 1 nm or less in thickness in some examples.

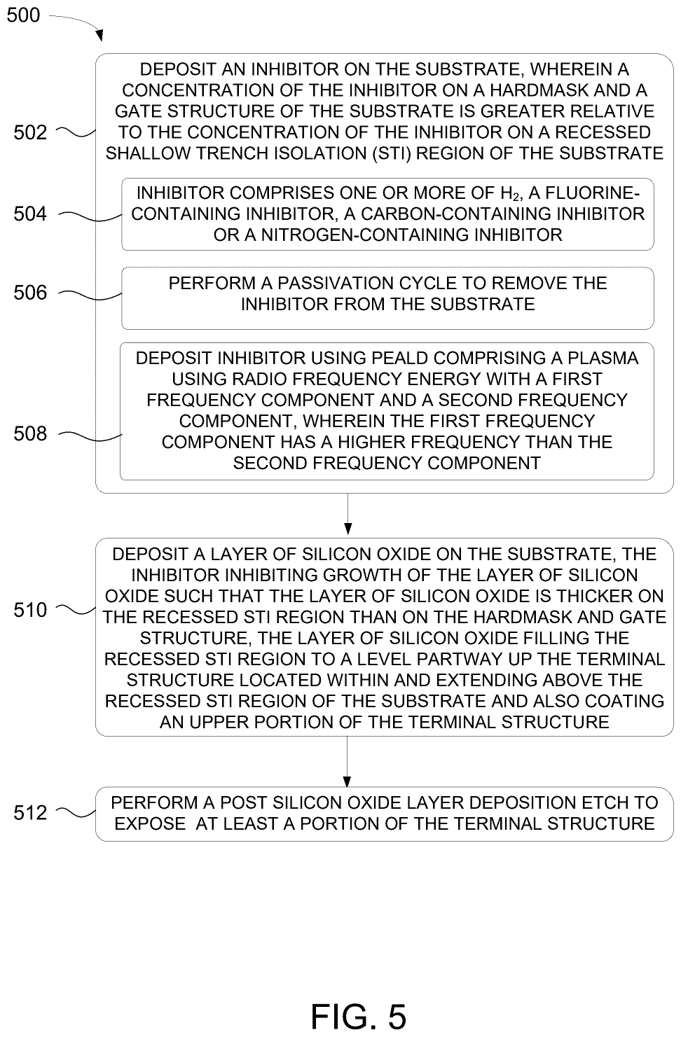

FIG. 5 shows a flow diagram depicting an example method 500 for processing a substrate comprising a hardmask disposed on a gate structure. The substrate also comprises a recessed STI region adjacent to the gate structure. The substrate further comprises a terminal structure located within the recessed STI region. The terminal structure extends above the recessed STI region.

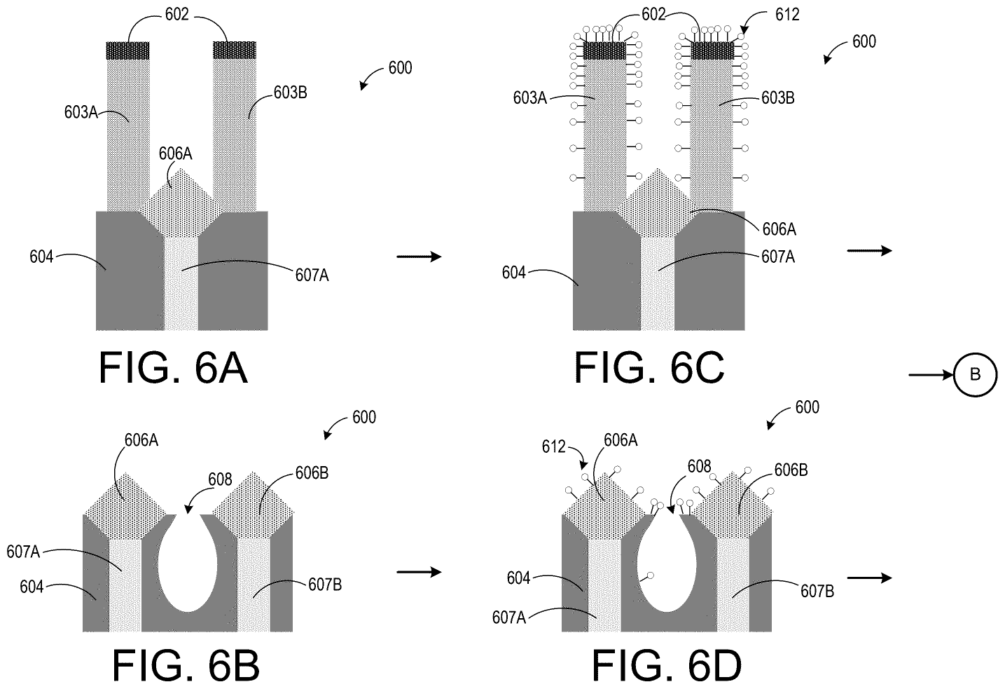

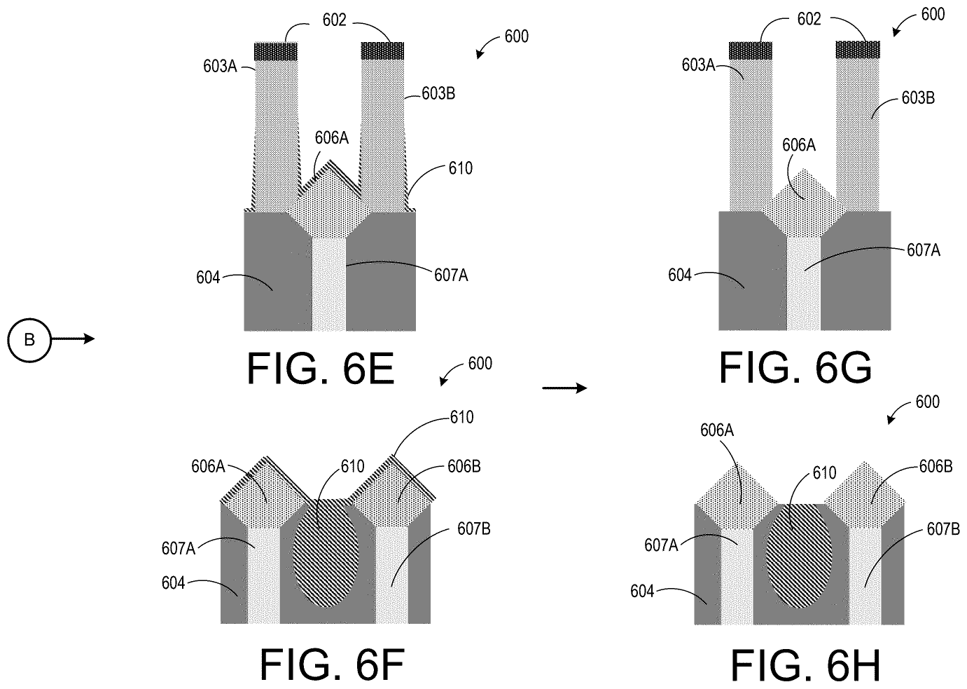

FIGS. 6A and 6B show cross-sections of an example substrate 600. The cross-sections in FIGS. 6A and 6B are orthogonal views of the substrate 600. The substrate 600 comprises a hardmask 602 disposed on gate structures 603A, 603B. The substrate 600 also comprises a recessed STI region 604 and terminal structures 606A, 606B formed on polysilicon 607A, 607B, respectively. The recessed STI region 604 comprises a recess 608.

The method 500 comprises, at step 502, depositing an inhibitor on the substrate, wherein a concentration of the inhibitor on a hardmask and a gate structure of the substrate is greater relative to the concentration of the inhibitor on a recessed STI region of the substrate 604. This is shown schematically in orthogonal views FIGS. 6C and 6D. An inhibitor 612 deposits at a higher concentration on the top surfaces of the gate compared to the lower regions close to the terminal structures 606A, 606B. FIG. 6D shows that the inhibitor 612 comprises a higher concentration on the entrant region of the recess 608 compared to deeper within the recess 608. Further, the terminal structures 606A, 606B comprise a higher concentration of inhibitor compared to the recessed STI region 604.

Any suitable inhibitor may be used. In some examples the inhibitor may comprise one or more of a fluorine-containing inhibitor, a carbon-containing inhibitor, or a nitrogen-containing inhibitor, as indicated at step 504 in FIG. 5. In some examples, an inhibitor may comprise H₂ mixed with another species, such as N₂.

In some examples, the inhibitor may be removed by a passivation cycle, as indicated at step 506 in FIG. 5. Passivation cycles, silicon oxide deposition and inhibitor deposition cycles may be performed in different permutations and combinations, as discussed below. In other examples, the inhibitor may be removed without a passivation cycle. For example, a carbon-containing inhibitor may be removed by oxidation during film precursor oxidation.

As described above, the inhibitor may be deposited on the substrate under processing conditions such that the concentration of the inhibitor is higher on surfaces where less or no silicon oxide deposition is desired. In some examples, the inhibitor may be deposited using PEALD. In some such examples, the PEALD process may comprise a plasma with a higher frequency RF energy and a lower frequency RF energy component as indicated at step 508, as described above.

The method 500 further comprises, at step 510, depositing a layer of silicon oxide on the substrate. The inhibitor inhibits growth of the layer of silicon oxide such that the layer of silicon oxide is thicker on the recessed STI region and thinner on the hardmask and gate structure. Referring to orthogonal views FIGS. 6E and 6F, the process may be controlled such that silicon oxide deposition fills the recess in the recessed STI region 604. The top surfaces of the terminal structures 606A, 606B have a coating of silicon oxide. Gate structures 603A, 603B have less silicon oxide deposition than the recess in the recessed STI region 604. The recessed 608 is filled with silicon oxide. Also, the surfaces of the terminal structures 606A, 606B and the gate structures 603A, 603B have a lesser amount of silicon oxide deposition 610.

The method 500 further comprises, at step 512, performing a post silicon oxide layer deposition wet etch to expose at least a portion of the terminal structure. This is shown schematically in orthogonal views FIGS. 6G and 6H, with upper portions of the terminal structures 606A, 606B exposed. Any suitable wet etch process may be used. In some examples, a wet etch chemistry may include dilute HF. The wet etch may be performed for a sufficient time such that the surfaces of the terminal structures 606A, 606B are exposed. Similarly, silicon oxide may be removed from the sides of the gate structures 603A, 603B.

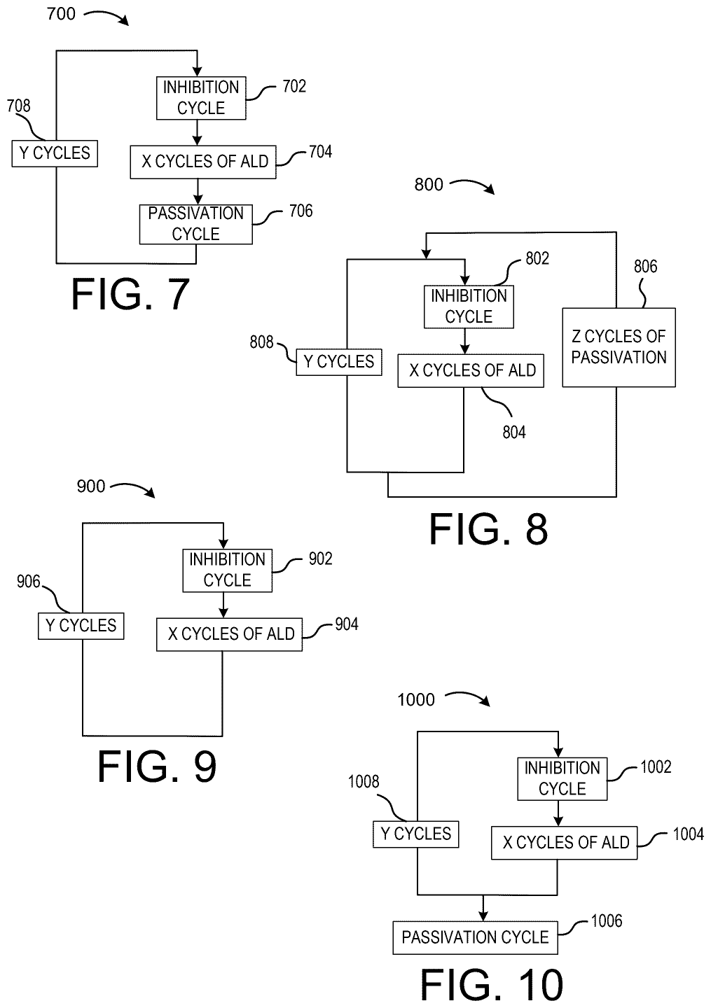

As discussed earlier, the passivation cycles, silicon oxide deposition and inhibition cycles may be performed in various permutations and combinations. A selected deposition process may depend on factors such as the substrate, choice of inhibitor and silicon oxide deposition conditions. In some examples, processing times and throughput may also be a factor. FIGS. 7-13 show various examples of permutations of inhibition, silicon oxide deposition and passivation cycles.

First, FIG. 7 shows a flow diagram depicting an example method 700 for performing ALD silicon oxide deposition with an inhibition cycle 702 and a passivation cycle 706. Method 700 comprises an inhibition cycle 702 and X number of ALD cycles 704 to help achieve nonconformal silicon oxide film deposition. X represents an integer greater than or equal to one. The inhibition cycle 702 may comprise introduction of any suitable inhibitor. Examples include a nitrogen-containing inhibitor, a fluorine-containing inhibitor, or a carbon-containing inhibitor. In some examples, an inhibitor may comprise H₂ mixed with another species, such as N₂. More detailed examples of inhibitors are given above. The inhibition cycle deposits a relatively greater concentration of inhibitor on the hardmask and gate structure and a lower concentration of the inhibitor on the recessed STI region.

The inhibitor may be deposited using a PEALD process in the inhibition cycle 702. The PEALD process may comprise a higher frequency energy component and a lower frequency energy component in some examples. In some examples, the higher frequency RF energy component may be varied in the range of 50-1500 W. Increasing the energy of the higher frequency component may lead to stronger inhibition. The lower frequency component may be used to direct the inhibitor to the substrate. The lower frequency RF energy component may be varied in the range of 0-1500 W in some examples. Increasing the energy of the lower frequency component may lead to stronger inhibition. Increasing the inhibition time, the inhibitor partial pressure and the inhibitor flow rate may also lead to stronger inhibition. In some examples, the inhibition time may comprise a time within a range of 0.1-30 s. Further, in some examples, the inhibitor flow rate may comprise a flow within a range of 5-250 sccm. In other examples, one or more suitable values outside of the stated ranges may be used for one or more of the above-described parameters.

At 704, method 700 performs X number of ALD cycles. Any suitable number X of ALD cycles may be performed at 1204. After performing an inhibition cycle at 702 and X number of ALD cycles at 704, method 700 comprises performing a passivation cycle at 706. As described above, a passivation cycle can be performed to remove residual inhibitor from the substrate.

The inhibition cycle performed at 702, the ALD cycle(s) performed at 704, and the passivation cycle performed at 706 may be repeated any suitable number Y of times, as indicated at 708. Y is an integer greater than or equal to one. Thus, method 700 includes one passivation cycle for X number of ALD cycles. A greater ratio of ALD cycles to inhibition cycle may result in a greater degree of conformality of the silicon oxide film. The degree of conformality of silicon oxide deposition may thus be modulated through an entire silicon oxide deposition process. This applies to all methods 700, 800, 900, 1100, 1200, and 1300. Once a target oxide film has been deposited, method 700 may terminate.

In some examples, passivation may be performed at different intervals than inhibition. FIG. 8 shows an example method 800 for performing a sequence that comprises a subcycle comprising an inhibition cycle 802 and X number of ALD cycles 804. The subcycle is performed Y times as indicated at 808, and then Z number of passivation cycles 806 is performed. The numbers X, Y and Z independently each may be an integer equal to or greater than one.

In some examples, an inhibitor may be removed by the silicon oxide deposition process. In such examples, a passivation cycle may be omitted. FIG. 9 shows a flow diagram of an example method 900 comprising an inhibition cycle 902 and X number of ALD cycles 904 performed Y times, as indicated at 906. Method 900 omits a passivation cycle. As one example, carbon may be oxidized along with the adsorbed silicon-containing species during the oxidation cycle of a silicon oxide deposition. The numbers X and Y independently each may be an integer equal to or greater than one.

A greater ratio of ALD cycles to inhibition cycles may result in a greater degree of conformality of the silicon oxide film. The degree of conformality of silicon oxide deposition may thus be modulated through an entire silicon oxide deposition process. Once a target oxide film has been achieved, method 900 may terminate.

In some examples, a single passivation cycle may be performed at the end of the silicon oxide deposition so that the surfaces of the terminal structures may be free of any physiosorbed and/or chemisorbed inhibitor. FIG. 10 shows an example method 1000 for performing ALD processing with a final passivation cycle.

Method 1000 comprises performing an inhibition cycle 1002 followed by X number of ALD cycles 1004. This is repeated Y times, as indicated at 1008. The numbers X and Y independently each may be an integer equal to or greater than one. A greater ratio of ALD cycles to inhibition cycles may result in a greater degree of conformality of the silicon oxide film. The degree of conformality of silicon oxide deposition may thus be modulated through the entire silicon oxide deposition process.

Once a target oxide film has been deposited, method 1000 may proceed to 1006 and perform a passivation cycle. After performing the passivation cycle at 1006, method 1000 may terminate.

Various process variables may be adjusted to affect a degree of film conformality. As described above, a ratio of ALD cycles to inhibition cycles may be adjusted to control a degree of nonconformal growth. As another example, varying a time of exposure to the inhibitor may vary the conformality of the silicon oxide film. Additionally, one or more passivation cycles may be performed during ALD processing to remove residual inhibitor from the substrate. In some examples, when performing ALD with a fluorine-containing inhibitor, the one or more passivation cycles may help to avoid incorporation of fluorine into the oxide film. In some examples, a passivation cycle can be performed at the end of ALD processing. In some examples, passivation cycles additionally or alternatively are performed between ALD cycles.

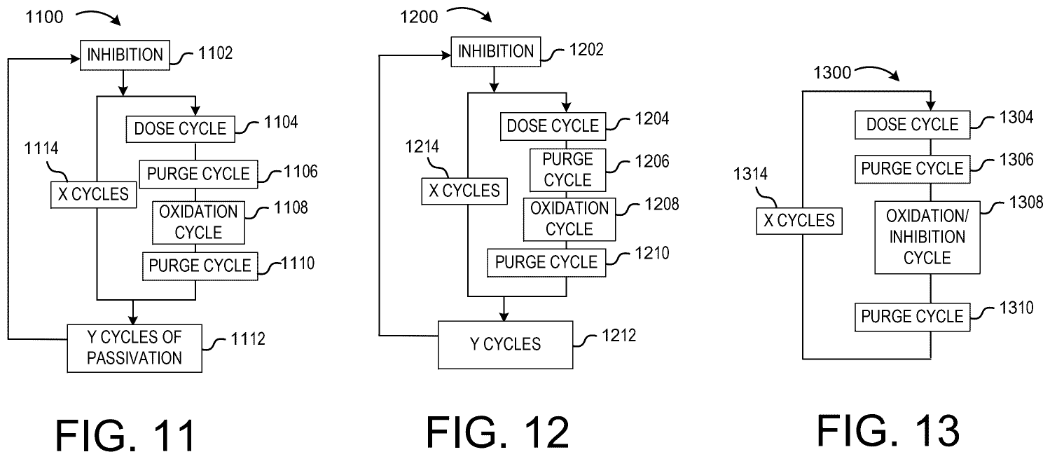

In some examples, an inhibition cycle, ALD deposition cycle and passivation cycles may be performed at the same pressure, temperature, and/or gas flow rate. FIGS. 11-13 illustrate example methods in which inhibition cycles, ALD cycles and the passivation cycles are performed at one or more of a same process pressure, temperature, or gas flow rate.

FIG. 11 shows an example method 1100 for performing ALD processing with an inhibition cycle 1102 and a passivation cycle 1112 that may be performed at a same pressure and/or flow rate. Method 1100 comprises an inhibition cycle 1102, a dose cycle 1104, a purge cycle 1106, an oxidation cycle 1108 and another purge cycle 1110. These cycles are repeated X number of times. The number X comprises an integer greater than or equal to one.

The dose cycle 1104 comprises flowing a silicon-containing precursor on the substrate. In a silicon oxide deposition process, any suitable silicon-containing precursor may be used. Examples include those given above. In some examples, a plasma may be used to deposit the silicon-containing species on the substrate.

The excess silicon-containing precursor and any byproducts may be purged during the purge cycle 1106. A purge gas may be used during this cycle. A purge gas may comprise any suitable inert gas. Examples include one or more of argon, nitrogen, krypton or xenon. In some examples, a plurality of purge gases may be used.

The oxidation cycle at 1108 comprises introducing an oxidant to oxidize the physisorbed and/or chemisorbed silicon-containing precursor to form silicon oxide. Any suitable oxidant may be used. Example oxidants comprise one or more of oxygen (O₂), ozone (O₃), one or more oxides of nitrogen (e.g. N₂O), water vapor (H₂O), or hydrogen peroxide (H₂O₂). In some examples, a plasma may be used to excite the oxidant to ensure proper oxidation of the adsorbed silicon-containing species.

Any byproducts formed during the oxidation cycle and excess oxygen may be removed from the system during the purge cycle 1110. This may comprise flowing a purge gas through the system. A purge gas may comprise of one or more of any suitable inert gas. Excess oxygen and byproducts and the purge gas may be continuously removed from the system during the purge cycle.

After performing processes 1104-1110 X times, method 1100 comprises performing Y number of cycles of passivation, where Y is an integer greater than or equal to one. After Y number of cycles of passivation, inhibition 1102 and ALD deposition processes 1104-1110 may be performed again if desired. Once a target oxide film has been achieved, method 1100 may terminate.

In some examples, the substrate is heated via a substrate heater during processing. In some examples, the substrate heater may be heated to a temperature within a range of 150° C. to 400° C. The inhibition cycles, the different steps of the ALD process and the passivation cycle may generally be performed at the same temperature. Further, as mentioned above, the process pressure and/or gas flow rate during the inhibition cycles, the silicon oxide deposition process and the passivation cycle may remain the same.

FIG. 12 shows another example method 1200 for performing inhibited ALD in which inhibition, ALD deposition and passivation may be performed at a same pressure, temperature and/or gas flow rate. Method 1200 omits a passivation cycle. Thus, method 1200 may be suitable for use with an inhibitor such as carbon that is removed during an oxidation cycle. Method 1200 comprises performing an inhibition cycle 1202. Method 1200 further comprises performing silicon oxide deposition using an ALD process. The ALD process comprises a dose cycle 1204, a purge cycle 1206, an oxidation cycle 1208 and another purge cycle 1210. These cycles may be performed as described above with regard to FIG. 11. Dose cycle 1204, purge cycle 1206, oxidation cycle 1208 and purge cycle 1210 may be performed X number of times, where X is an integer greater than or equal to one. Further, after X number of cycles, method 1200 may again apply an inhibitor at 1202. Cycle 1212, followed by X number of cycles of 1204-1210, is repeated Y times, where Y is an integer greater than or equal to one.

FIG. 13 shows another example method 1300 for performing inhibited ALD in which inhibition, ALD deposition and passivation may be performed at a same pressure, temperature and/or gas flow rate. In method 1300, inhibition and oxidation are performed in a same stage. More particularly, method 1300 performs X number of an ALD cycle comprising a dose cycle 1304, a purge cycle 1306, an oxidation and inhibition cycle 1308, and another purge cycle 1310.

In the oxidation and inhibition cycle 1308, an oxidant and an inhibitor are introduced. The oxidant oxidizes the silicon oxide precursor introduced in dose cycle 1304. The inhibitor may comprise one or more of a fluorine-containing inhibitor, a carbon-containing inhibitor, or a nitrogen-containing inhibitor. In some examples, an inhibitor may comprise H₂ mixed with another species, such as N₂. In some examples, the inhibitor may be deposited on the substrate using a plasma that is also used to oxidize the silicon oxide precursor.

Any byproducts formed during the oxidation cycle, excess inhibitor and excess oxygen may be removed from the system during the purge cycle 1310. This may comprise flowing a purge gas through the system. A purge gas may comprise any suitable inert gas or gases.

Continuing X number of ALD cycles may be performed as indicated at 1314. Any suitable number X of ALD cycles may be performed at 1314. Once a sufficient silicon oxide film thickness has been achieved, method 1200 may terminate. In some examples, the substrate is heated via a substrate heater during processing. In some examples, the substrate heater may be heated to a temperature within a range of 150° C. to 400° C. In other examples, a temperature outside of this range may be used. The different steps of the ALD process may generally be performed at the same temperature. By performing a combined inhibition/oxidation, an overall processing time may be reduced. This may lead to higher throughput.

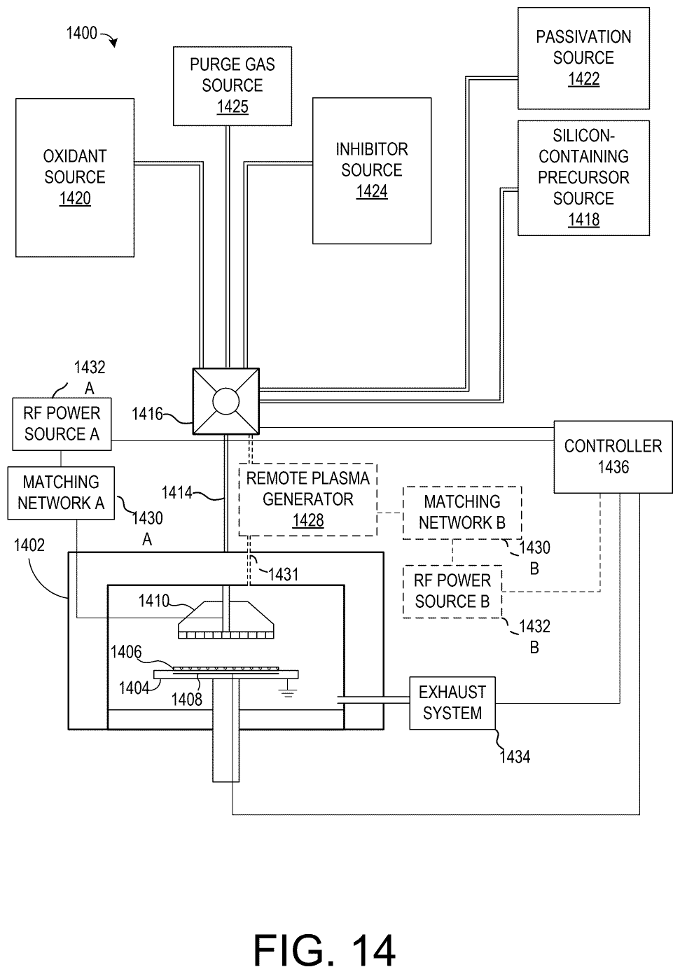

FIG. 14 shows a schematic view of an example processing tool 1400 for performing an ALD process to deposit silicon oxide films using an inhibitor. Processing tool 1400 comprises a processing chamber 1402. Processing tool 1400 further comprises a substrate support 1404 within the processing chamber for supporting a substrate 1406. Substrate support 1404 may comprise a pedestal, a chuck, and/or any other suitable structure. Substrate support 1404 further may include a substrate heater 1408.

Processing tool 1400 further comprises one or more processing gas inlets for introducing processing gases into processing chamber 1402. One example processing gas inlet is shown a processing gas inlet 1414 for admitting a flow of one or more processing gases.

In the depicted example, processing gas inlet 1414 directs processes gases to a showerhead 1410. In other examples, a nozzle and/or other suitable inlet hardware may be used. Processing tool 1400 further comprises flow control hardware 1416 for controlling the introduction of processing gases into processing chamber 1402. Flow control hardware is connected to a silicon-containing precursor source 1418, an oxidant source A 1420, a passivation source 1422, an inhibitor source 1424, and a purge gas source 1425.

Silicon-containing precursor source 1418 comprises any suitable silicon-containing precursor. Example silicon-containing precursors may comprise materials having the general structure:

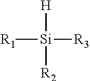

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups. More specific example silicon-containing precursors include polysilanes (H₃Si—(SiH₂)ₙ—SiH₃), where n≥1, such as silane, disilane, trisilane, tetrasilane, and trisilylamine. In some examples, the silicon-containing precursor is an alkoxysilane. Alkoxysilanes that may be used include the following: Hₓ—Si—(OR)_{y}, where x=1-3, x+y=4 and each R is a substituted or unsubstituted alkyl, alkenyl, alkynyl or aromatic group; and Hₓ(RO)_{y}, —Si—Si—(OR)_{y}Hₓ, is a substituted or unsubstituted alkyl, alkenyl, alkynyl or aromatic group. Further examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS). In some examples, the silicon-containing precursor may comprise a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS). Further, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino)silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group. In some examples, a halogen-containing silane may be used such that the silane includes at least one hydrogen atom. Such a silane may have a chemical formula of SiXₐH_{y} where y 1. For example, dichlorosilane (H₂SiCl₂) may be used in some examples.

Likewise, an inhibitor source 1424 may comprise one or more of a fluorine-containing inhibitor, a carbon-containing inhibitor, or a nitrogen-containing inhibitor. Example fluorine-containing inhibitor may include one or more of F₂, NF₃, CF₄, SF₆, HF or XeF₂. Example nitrogen-containing inhibitor may include one or more of N₂, NH₃, amines, diamines or aminoalcohols. In some examples, an inhibitor may comprise H₂ mixed with another species, such as N₂. Example carbon-containing inhibitor may include one or more of an alkane, an alkene, an alkyne, a cyclic hydrocarbon, an alcohol, a diol, an aldehyde, an ester, an ether, a ketone, an alkyl halide, an alkyl amine, or an alkyl diamine. More detailed examples of inhibitors are given above.

Oxidant source A 1420 may comprise any suitable oxidant that may be used to oxidize silicon-containing precursor adsorbed on the substrate during a silicon oxide deposition cycle. In some examples, oxidant source A 1420 may be used to oxidize metal-containing precursor adsorbed on the substrate during a metal oxide deposition cycle. Example oxidants comprise one or more of oxygen (O₂), ozone (O₃), one or more oxides of nitrogen (e.g. N₂O), water vapor (H₂O), or hydrogen peroxide (H₂O₂).

Purge gas source 1425 may comprise any suitable inert gas. Examples include one or more of argon, nitrogen, krypton or xenon. In some examples, one or more additional purge gas sources may be included, each providing a different purge gas.

Processing tool 1400 further comprises an exhaust system 1434. Exhaust system 1434 is configured to remove gases from processing chamber 1402. Exhaust system 1434 may comprise any suitable hardware. Example hardware includes one or low vacuum pumps and/or one or more high vacuum pumps.

In some examples, substrate heater 1408 is used to provide thermal energy to facilitate the ALD process. In other examples, a plasma to facilitate the ALD process alternatively or additionally may be generated inside processing chamber 1402 using a radiofrequency (RF) power source A 1432A and a matching network A 1430A. The plasma may be used to provide the energy to generate chemically active species in the gas phase. In other examples, a remote plasma generator 1428 may be used to provide reactive species for one or more of an ALD process, an inhibition cycle or a passivation cycle.

In other examples, a remote plasma is generated via an optional remote plasma generator 1428 to produce reactive species, in addition or alternatively to heating the substrate. The remote plasma may form a reactive and/or intermediate species drive one or more of the ALD reaction, inhibition cycle or the passivation cycle. Remote plasma generator 1428 may be omitted in some examples. Chemical species from remote plasma generator 1428 may be introduced into processing chamber 1402 via gas inlet 1431. In other examples, remote plasma generator 1428 may be configured to introduce chemical species into processing chamber 1402 via gas inlet 1414 and showerhead 1410.

Where optional remote plasma generator 1428 is used, processing tool 1400 may further comprise a radiofrequency power source B 1432B electrically connected to remote plasma generator 1428. Processing tool 1400 further may comprise a matching network B 1430B for impedance matching of the radiofrequency power source 232B.

Radiofrequency power source A 1432A and radiofrequency power source B 1432B may be configured for any suitable frequency and power. Examples of suitable frequencies include 400 kHz, 13.56 MHz, 27 MHz, 60 Mz, and 90 MHz. Examples of suitable powers include powers between 50 W (watts) and 50 kW. In some examples, radiofrequency power sources 1432A and 1432B may be configured to operate at a plurality of different frequencies and/or powers.

Flow control hardware 1416 may be controlled to flow processing chemicals from sources 1418, 1420, 1422, 1424 and 1425 into processing chamber 1402 via gas inlet 1414. In some examples, flow control hardware 1416 may also be configured to control the flow of one or more chemicals into remote plasma generator 1428. Flow control hardware 1416 schematically represents any suitable components related to flowing gas into processing chamber 1402 (and remote plasma generator 1428 in some examples). For example, flow control hardware 1416 may comprise one or more mass flow controllers and/or valves controllable to place a selected chemical source in fluid connection with processing chamber 1402.

Controller 1436 is operatively coupled to substrate heater 1408, flow control hardware 1416, remote plasma generator 1428, exhaust system 1434, radiofrequency power source A 1432A, and radiofrequency power source B 1432B. Controller 1436 further may be operatively coupled to any other suitable component of processing tool 1400. Controller 1436 is configured to control various functions of processing tool 1400 to perform a layered film deposition process. Controller 1436 is also configured to control various functions of the processing tool 1400 to perform a chamber cleaning process.

For example, controller 1436 is configured to operate substrate heater 1408 to heat a substrate. Controller 1436 is also configured to operate flow control hardware 1416 to flow a selected chemical or mixture of chemicals at a selected rate into processing chamber 1402. Controller 1436 is also configured to operate exhaust system 1434 to remove gases from processing chamber 1402. Controller 1436 is further configured to operate flow control hardware 1416 and exhaust system 1434 to maintain a selected pressure within processing chamber 1402. Controller 1436 is further configured to control the power source 1432A to control the plasma generated in the chamber. Furthermore, controller 1436 is configured to operate optional remote plasma generator 1428 and/or radiofrequency power source 1432B to form a remote plasma.

In some embodiments, the methods and processes described herein may be tied to a computing system of one or more computing devices. In particular, such methods and processes may be implemented as a computer-application program or service, an application-programming interface (API), a library, and/or other computer-program product.

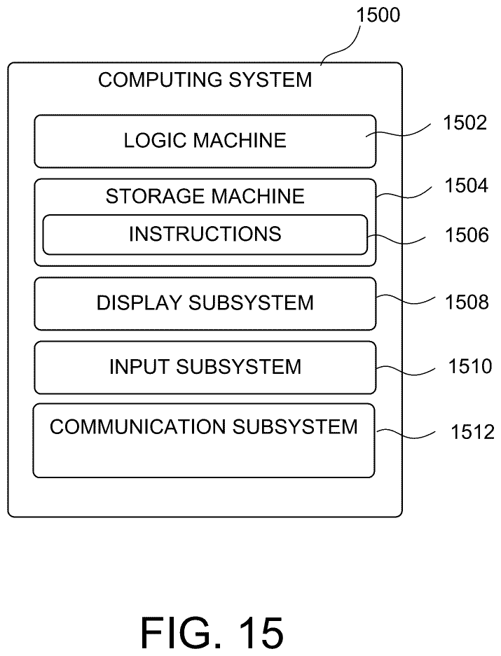

FIG. 15 schematically shows an example of a computing system 1500 that can enact one or more of the methods and processes described above. Computing system 1500 is shown in simplified form. Computing system 1500 may take the form of one or more personal computers, server computers, tablet computers, home-entertainment computers, network computing devices, gaming devices, mobile computing devices, mobile communication devices (e.g., smart phone), and/or other computing devices. Controller 1436 in FIG. 14 is an example of computing system 1500.

Computing system 1500 includes a logic machine 1502 and a storage machine 1504. Computing system 1500 may optionally include a display subsystem 1508, input subsystem 1510, communication subsystem 1512, and/or other components not shown in FIG. 15.

Logic machine 1502 includes one or more physical devices configured to execute instructions 1506. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1504 includes one or more physical devices configured to hold instructions 1506 executable by the logic machine to implement the methods and processes described herein. When such methods and processes are implemented, the state of storage machine 1504 may be transformed—e.g., to hold different data.

Storage machine 1504 may include removable and/or built-in devices. Storage machine 1504 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1504 may include volatile, nonvolatile, dynamic, static, read/write, read-only, random-access, sequential-access, location-addressable, file-addressable, and/or content-addressable devices.

It will be appreciated that storage machine 1504 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1502 and storage machine 1504 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1508 may be used to present a visual representation of data held by storage machine 1504. This visual representation may take the form of a graphical user interface (GUI). As the herein described methods and processes change the data held by the storage machine, and thus transform the state of the storage machine, the state of display subsystem 1508 may likewise be transformed to visually represent changes in the underlying data. Display subsystem 1508 may include one or more display devices utilizing virtually any type of technology. Such display devices may be combined with logic machine 1502 and/or storage machine 1504 in a shared enclosure, or such display devices may be peripheral display devices.

When included, input subsystem 1510 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; an infrared, color, stereoscopic, and/or depth camera for machine vision and/or gesture recognition; a head tracker, eye tracker, accelerometer, and/or gyroscope for motion detection and/or intent recognition; as well as electric-field sensing componentry for assessing brain activity.

When included, communication subsystem 1512 may be configured to communicatively couple computing system 1500 with one or more other computing devices. Communication subsystem 1512 may include wired and/or wireless communication devices compatible with one or more different communication protocols. As examples, the communication subsystem may be configured for communication via a wireless telephone network, or a wired or wireless local- or wide-area network. In some embodiments, the communication subsystem may allow computing system 1500 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of processing a substrate, the method comprising:
depositing an inhibitor on the substrate, wherein a concentration of the inhibitor on a gate structure of the substrate is greater relative to a concentration of the inhibitor on a recessed shallow trench isolation (STI) region of the substrate; and
depositing a layer of silicon oxide on the substrate, the inhibitor inhibiting growth of the layer of silicon oxide such that the layer of silicon oxide is thicker on the recessed shallow trench isolation region than on the gate structure.

2. The method of claim 1, wherein the inhibitor comprises one or more of hydrogen, a fluorine-containing inhibitor, a carbon-containing inhibitor, or a nitrogen-containing inhibitor.

3. The method of claim 2, wherein the inhibitor comprises one or more of hydrogen, fluorine, nitrogen, nitrogen trifluoride, carbon tetrafluoride, sulfur hexafluoride, hydrogen fluoride, xenon difluoride, ammonia, an amine, a diamine, an aminoalcohol, alkane, an alkene, an alkyne, a cyclic hydrocarbon, an alcohol, a diol, an aldehyde, an ester, an ether, a ketone, an alkyl halide, an alkyl amine, or an alkyl diamine.

4. The method of claim 1, further comprising performing a passivation cycle to remove the inhibitor from the substrate.

5. The method of claim 4, wherein performing the passivation cycle comprises performing the passivation cycle after completing a plurality of oxide deposition cycles.

6. The method of claim 4, wherein the passivation cycle is performed after completing a first portion of oxide deposition cycles and before completing a second portion of oxide deposition cycles.

7. The method of claim 1, wherein inhibitor is deposited at first pressure and silicon oxide is deposited at second, different pressure.

8. The method of claim 1, wherein inhibitor and silicon oxide are deposited at a same pressure.

9. The method of claim 1, wherein depositing the inhibitor comprises depositing the inhibitor using plasma enhanced atomic layer deposition.

10. The method of claim 9, wherein depositing the inhibitor using plasma enhanced atomic layer deposition comprises depositing the inhibitor using radio frequency energy with a first frequency component and a second frequency component, wherein the first frequency component has a higher frequency than the second frequency component.

11. The method of claim 1, wherein the substrate comprises a terminal structure within the recessed shallow trench isolation region, and wherein the method further comprises performing a post silicon oxide layer deposition etch to expose at least a portion of the terminal structure.

12. A method of processing a substrate, the method comprising:
depositing an inhibitor on the substrate, wherein a concentration of the inhibitor on a hardmask and a gate structure of the substrate is greater relative to the concentration of the inhibitor on a recessed shallow trench isolation (STI) region of the substrate; and
depositing a layer of silicon oxide on the substrate, the inhibitor inhibiting growth of the layer of silicon oxide such that the layer of silicon oxide is thicker on the recessed shallow trench isolation region than on the hardmask and gate structure, the layer of silicon oxide overfilling the recessed shallow trench isolation region to cover a terminal structure located within and extending above the recessed shallow trench isolation region of the substrate; and
performing a post silicon oxide layer deposition etch to expose at least a portion of the terminal structure.

13. The method of claim 12, wherein the inhibitor comprises one or more of a fluorine-containing inhibitor, a carbon-containing inhibitor, or a nitrogen-containing inhibitor.

14. The method of claim 12, further comprising performing a passivation cycle to remove the inhibitor from the substrate.

15. The method of claim 12, wherein depositing the inhibitor comprises depositing the inhibitor using plasma enhanced atomic layer deposition comprising a plasma using radio frequency energy with a first frequency component and a second frequency component, wherein the first frequency component has a higher frequency than the second frequency component.

16. A method of processing a substrate, the method comprising:
depositing an inhibitor on the substrate, wherein a concentration of the inhibitor on a hardmask and a gate structure of the substrate is greater relative to the concentration of the inhibitor on a recessed shallow trench isolation (STI) region of the substrate; and
depositing a layer of silicon oxide on the substrate, the inhibitor inhibiting growth of the layer of silicon oxide such that the layer of silicon oxide is thicker on the recessed shallow trench isolation region than on the hardmask and gate structure, the layer of silicon oxide filling the recessed shallow trench isolation region to a level partway up a terminal structure located within and extending above the recessed shallow trench isolation region of the substrate and also coating an upper portion of the terminal structure; and
performing a post silicon oxide layer deposition etch to expose at least a portion of the terminal structure.

17. The method of claim 16, wherein the inhibitor comprises one or more of a fluorine-containing inhibitor, a carbon-containing inhibitor, or a nitrogen-containing inhibitor.

18. The method of claim 16, wherein the inhibitor comprises one or more of hydrogen, fluorine, nitrogen, nitrogen trifluoride, carbon tetrafluoride, sulfur hexafluoride, hydrogen fluoride, xenon difluoride, ammonia, an amine, a diamine, an aminoalcohol, an alkane, an alkene, an alkyne, a cyclic hydrocarbon, an alcohol, a diol, an aldehyde, an ester, an ether, a ketone, an alkyl halide, an alkyl amine, or an alkyl diamine.

19. The method of claim 16, further comprising performing a passivation cycle to remove the inhibitor from the substrate.

20. The method of claim 16, wherein depositing the inhibitor comprises depositing the inhibitor using plasma enhanced atomic layer deposition comprising a plasma using radio frequency energy with a first frequency component and a second frequency component, wherein the first frequency component has a higher frequency than the second frequency component.
